(19) United States
(12) Patent Application Publication
(10) Pub. No.: US 2024/0168385 A1
(43) Pub. Date: May 23, 2024

(54) PROTECTIVE FILM-FORMING COMPOSITION

(71) Applicant: NISSAN CHEMICAL CORPORATION, Tokyo (JP)

(72) Inventors: Tokio NISHITA, Toyama (JP); Yuto HASHIMOTO, Gyeonggi-do (KR); Yuki ENDO, Toyama (JP)

(73) Assignee: NISSAN CHEMICAL CORPORATION, Tokyo (JP)

(21) Appl. No.: 18/279,766

(22) PCT Filed: Mar. 3, 2022
(86) PCT No.: PCT/JP2022/009008

§ 371 Date: Aug. 31, 2023

(30) Foreign Application Priority Data
Mar. 4, 2021 (JP) 2021-034570

(51) Int. Cl. G03F 7/16; C08G 59/20; G03F 7/004; G03F 7/11; G03F 7/40

(52) U.S. Cl. CPC G03F 7/168; C08G 59/20; G03F 7/0045; G03F 7/0048; G03F 7/11; G03F 7/40

(57) ABSTRACT

A protection film formation composition for a wet-etching solution for semiconductors, the protection film formation composition including: (A) a compound having no repeating structural unit and contains a terminal group (A1), a polyvalent group (A2) and a linking group (A3). Terminal group (A1) binds only to linking group (A3), polyvalent group (A2) binds only to linking group (A3), linking group (A3) binds to terminal group (A1) at one terminal and to polyvalent group (A2) at the other terminal and optionally binds to another linking group (A3), terminal group (A1) is represented by formula (I), polyvalent group (A2) represents a group having a valency of 2 to 4; and linking group (A3) represents an aromatic hydrocarbon group; (B) a thermoacid generator (B-1) and/or a curing agent (B-2); and (C) a solvent.

### TECHNICAL FIELD

The present invention relates to a composition for forming a protective film excellent in resistance to a semiconductor wet etching solution, particularly a basic hydrogen peroxide aqueous solution, in a lithography process for semiconductor manufacturing. The present invention also relates to a protective film obtained from the composition, a method for producing a substrate with a protective film, a resist underlayer film to which the composition is applied, a method for producing a substrate with a resist pattern, and a method for producing a semiconductor device.

### BACKGROUND ART

As the gate insulating film becomes thinner, current leakage between the gate electrode and the substrate increases, resulting in increased power consumption. For this reason, high-dielectric-constant films (high-k materials), which have a higher relative permittivity than SiO₂, are used as gate insulating films, and metal gates are used as gate electrodes combined with high-k materials. In a process of manufacturing a high-k metal gate, a protective film is provided on a substrate having a TiN film, a photoresist is applied, patterning is performed, and then TiN is removed by wet etching. The protective film used here is required to have resistance to chemical solutions, particularly resistance to an ammonia hydrogen peroxide solution (SC-1).

Patent Literature 1 discloses a protective film-forming composition against semiconductor wet etching solutions, including a compound containing at least one set of two hydroxy groups adjacent to each other in the molecule, or a polymer thereof, and a solvent.

### CITATION LIST

### Patent Literature

Patent Literature 1: WO 2019/124474 A

### SUMMARY OF INVENTION

### Technical Problem

It is desired to develop a technique for providing a protective film having a higher chemical resistance, particularly a resistance to ammonia hydrogen peroxide solution (SC-1).

### Solution to Problem

The present invention embraces the followings.

[1] A protective film-forming composition against semiconductor wet etching solutions, comprising:
(A) a compound having no repeating structural unit,
which contains a terminal group (A1), a multivalent group (A2), and a linking group (A3),
wherein the terminal group (A1) is bonded only to the linking group (A3),
the polyvalent group (A2) is bonded only to the linking group (A3), and
the linking group (A3) is bonded to the terminal group (A1) on one side and to the polyvalent group (A2) on the other, and may optionally be linked to another linking group (A3),
the terminal group (A1) has any of the structures of the following formula (I):

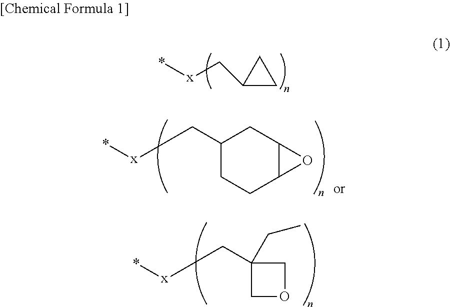

[in the formula (I), * represents a binding site with the linking group (A3),
X represents an ether bond, an ester bond, or a nitrogen atom; n=1 when X is an ether bond or an ester bond, and n=2 when X is a nitrogen atom],
the polyvalent group (A2) is a divalent to tetravalent group selected from the group consisting of:
—O—,
an aliphatic hydrocarbon group,
a combination of an aromatic hydrocarbon group having less than 10 carbon atoms with an aliphatic hydrocarbon group, and
a combination of an aromatic hydrocarbon group having 10 or more carbon atoms with —O—, and
the linking group (A3) represents an aromatic hydrocarbon group;
(B) a thermal acid generator (B-1) and/or a curing agent (B-2); and
(C) a solvent.
   [2] The protective film-forming composition according to [1], wherein the compound (A) is a compound represented by the following formula (II):

### [Chemical Formula 2]

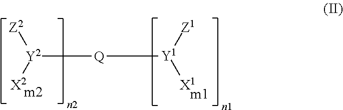

[in the formula (II), Z¹ and Z² each independently represent any of the following structures:

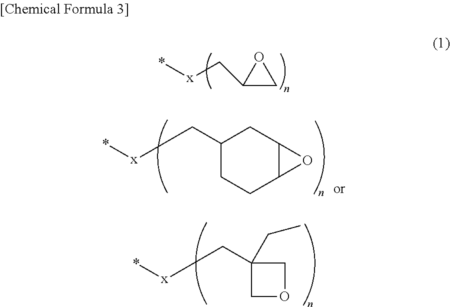

[in the formula (I), * represents a binding site with Y¹ or Y²,
X represents an ether bond, an ester bond, or a nitrogen atom; n=1 when X is an ether bond or an ester bond, and n=2 when X is a nitrogen atom],
Y¹ and Y² each independently represent an aromatic hydrocarbon group,
X¹ and X² each independently represent —Y¹—Z¹ or —Y²—Z²,
n1 and n2 each independently represent an integer of 0 to 4, provided that any one of n1 and n2 is 1 or more,
m1 and m2 each independently represent 0 or 1,
Q represents a divalent to tetravalent group selected from the group consisting of —O—, an aliphatic hydrocarbon group, a combination of an aromatic hydrocarbon group having less than 10 carbon atoms with an aliphatic hydrocarbon group, and a combination of an aromatic hydrocarbon group having 10 or more carbon atoms with —O—].
   [3] The protective film-forming composition according to [1],
wherein the compound (A) contains a partial structure represented by the following formula (III):

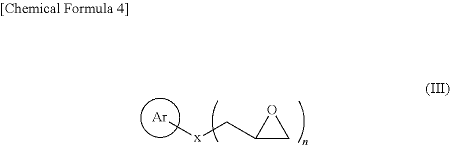

[in the formula (III), Ar represents a benzene ring, a naphthalene ring or an anthracene ring; X represents an ether bond, an ester bond, or a nitrogen atom; n=1 when X is an ether bond or an ester bond, and n=2 when X is a nitrogen atom].
[4] The protective film-forming composition according to any one of [1] to [3], wherein the compound (A) has a weight average molecular weight of 300 or more and 1,500 or less.
[5] The protective film-forming composition according to any one of [1] to [4], in which the composition is free from a novolak resin.
[6] The protective film-forming composition according to any one of [1] to [5], wherein each of the compound (A), the component (B), and the solvent (C) is free from a material containing one or more aromatic groups containing two or more substituents containing a hydroxy, thiol, and/or amine moiety.
[7] The protective film-forming composition according to any one of [1] to [6], wherein the compound (A) has two or more of the linking groups (A3).
[8] The protective film-forming composition according to any one of [1] to [7], wherein the component (B) comprises a curing agent (B-2) selected from the group consisting of phenolic curing agents, amide-based curing agents, amine-based curing agents, imidazoles, acid anhydride-based curing agents, and organic phosphines.
[9] The protective film-forming composition according to any one of [1] to [8], further comprising (D) a compound having one phenolic hydroxy group or a polymer having a unit structure having one phenolic hydroxy group.
[10] A protective film, which is a baked product of a coating film of the protective film-forming composition according to any one of [1] to [9].
[11] A resist underlayer film-forming composition comprising:
(A) a compound having no repeating structural unit,
which contains a terminal group (A1), a multivalent group (A2), and a linking group (A3),
wherein the terminal group (A1) is bonded only to the linking group (A3),
the polyvalent group (A2) is bonded only to the linking group (A3), and
the linking group (A3) is bonded to the terminal group (A1) on one side and to the polyvalent group (A2) on the other, and may optionally be linked to another linking group (A3),
the terminal group (A1) has any of the structures of the following formula (I):

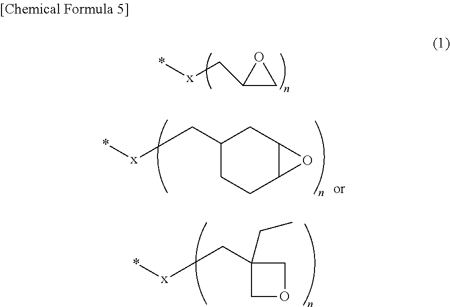

[in the formula (I), * represents a binding site with the linking group (A3),
X represents an ether bond, an ester bond, or a nitrogen atom; n=1 when X is an ether bond or an ester bond, and n=2 when X is a nitrogen atom],
the polyvalent group (A2) is a divalent to tetravalent group selected from the group consisting of: —O—,
an aliphatic hydrocarbon group,
a combination of an aromatic hydrocarbon group having less than 10 carbon atoms with an aliphatic hydrocarbon group, and
a combination of an aromatic hydrocarbon group having 10 or more carbon atoms with —O—, and
the linking group (A3) represents an aromatic hydrocarbon group;
(B) a thermal acid generator (B-1) and/or a curing agent (B-2); and
(C) a solvent.
   [12] The resist underlayer film-forming composition according to [11], wherein the compound (A) is a compound represented by the following formula (II):

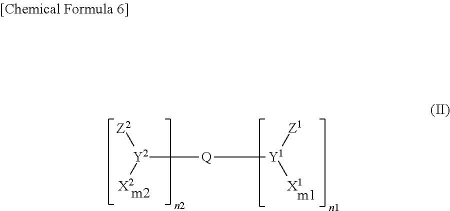

[in the formula (II), Z¹ and Z² each independently represent any of the following structures:

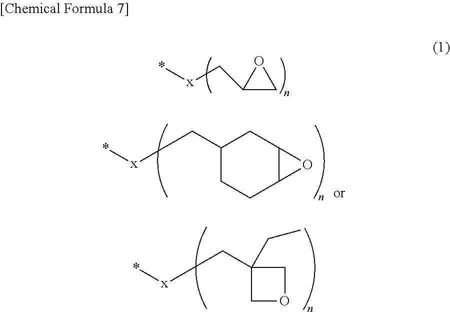

[in the formula (I), * represents a binding site with Y¹or Y²,
X represents an ether bond, an ester bond, or a nitrogen atom; n=1 when X is an ether bond or an ester bond, and n=2 when X is a nitrogen atom],

Y¹ and Y² each independently represent an aromatic hydrocarbon group,
X¹ and X² each independently represent —Y¹—Z¹ or —Y²—Z²,
n1 and n2 each independently represent an integer of 0 to 4, provided that any one of n1 and n2 is 1 or more,
m1 and m2 each independently represent 0 or 1,
Q represents a divalent to tetravalent group selected from the group consisting of —O—, an aliphatic hydrocarbon group, a combination of an aromatic hydrocarbon group having less than 10 carbon atoms with an aliphatic hydrocarbon group, and a combination of an aromatic hydrocarbon group having 10 or more carbon atoms with —O—].

The resist underlayer film-forming composition according to [11],
wherein the compound (A) contains a partial structure represented by the following formula (III):

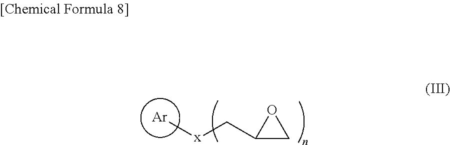

[in the formula (III), Ar represents a benzene ring, a naphthalene ring or an anthracene ring; X represents an ether bond, an ester bond, or a nitrogen atom; n=1 when X is an ether bond or an ester bond, and n=2 when X is a nitrogen atom].
[14] The resist underlayer film-forming composition according to any one of to [11] [13],
wherein the compound (A) has a weight average molecular weight of 300 or more and 1,500 or less.

[15] The resist underlayer film-forming composition according to any one of [11] to [14], wherein the composition is free from a novolak resin.

[16] The resist underlayer film-forming composition according to any one of [11] to [15], wherein each of the compound (A), the component (B), and the solvent (C) is free from a material containing one or more aromatic groups containing two or more substituents containing a hydroxy, thiol, and/or amine moiety.
[17] The resist underlayer film-forming composition according to any one of [11] to [16], wherein the compound (A) has two or more of the linking groups (A3).
[18] The resist underlayer film-forming composition according to any one of [11] to [17], wherein the component (B) comprises a curing agent (B-2) selected from the group consisting of phenolic curing agents, amide-based curing agents, amine-based curing agents, imidazoles, acid anhydride-based curing agents, and organic phosphines.
[19] The resist underlayer film-forming composition according to any one of [11] to [18], further comprising (D) a compound having one phenolic hydroxy group or a polymer having a unit structure having one phenolic hydroxy group.
[20] A resist underlayer film, which is a baked product of a coating film of the resist underlayer film-forming composition according to any one of [11] to [19].
[21] A method for producing a substrate with a protective film used in the manufacture of semiconductors, comprising applying the protective film-forming composition according to any one of [1] to [9] onto a stepped semiconductor substrate followed by baking thereof to form a protective film.
[22] A method for producing a substrate with a resist pattern used in the manufacture of semiconductors, comprising the steps of:
applying the protective film-forming composition according to any one of [1] to [9] or the resist underlayer film-forming composition according to any one of [11] to [19] onto a semiconductor substrate followed by baking thereof to form a protective film as a resist underlayer film; and
forming a resist film on the protective film followed by exposure and development thereof to form a resist pattern.
   [23] A method for producing a semiconductor device, comprising the steps of:
forming a protective film on a semiconductor substrate, which may have an inorganic film formed on its surface, with the protective film-forming composition according to any one of [1] to [9];
forming a resist pattern on the protective film;
dry etching the protective film using the resist pattern as a mask;
allowing a surface of the inorganic film or the semiconductor substrate to expose; and
wet etching and cleaning the inorganic film or the semiconductor substrate with a semiconductor wet etching solution using the dry-etched protective film as a mask.
   [24] A method for producing a semiconductor device, comprising the steps of:
forming a resist underlayer film on a semiconductor substrate, which may have an inorganic film formed on its surface, with the resist underlayer film-forming composition according to any one of [11] to [19];
forming a resist pattern on the resist underlayer film;
dry etching the resist underlayer film using the resist pattern as a mask;
allowing a surface of the inorganic film or the semiconductor substrate to expose; and
etching the inorganic film or the semiconductor substrate using the dry-etched resist underlayer film as a mask.

### Advantageous Effects of Invention

The protective film-forming composition according to the present invention can form a protective film exhibiting a high chemical resistance, good optical parameters, and a desirable dry etching selectivity in a lithography process for semiconductor manufacturing.

### Description of Embodiments

### Composition

A protective film-forming composition against semiconductor wet etching solutions according to the present invention comprises:
(A) a compound having no repeating structural unit,
which contains a terminal group (A1), a multivalent group (A2), and a linking group (A3),
wherein the terminal group (A1) is bonded only to the linking group (A3),
the polyvalent group (A2) is bonded only to the linking group (A3), and
the linking group (A3) is bonded to the terminal group (A1) on one side and to the polyvalent group (A2) on the other, and may optionally be linked to another linking group (A3),
the terminal group (A1) has any of the structures of the following formula (I):

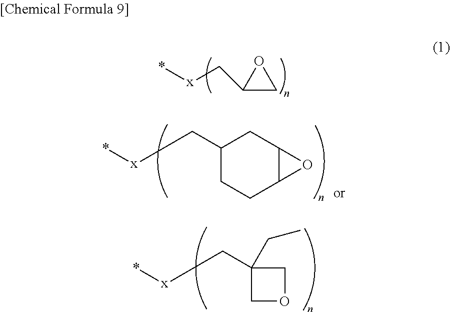

[in the formula (I), * represents a binding site with the linking group (A3),
X represents an ether bond, an ester bond, or a nitrogen atom; n=1 when X is an ether bond or an ester bond, and n=2 when X is a nitrogen atom],
the polyvalent group (A2) is a divalent to tetravalent group selected from the group consisting of:
—O—,
an aliphatic hydrocarbon group,
a combination of an aromatic hydrocarbon group having less than 10 carbon atoms with an aliphatic hydrocarbon group, and
a combination of an aromatic hydrocarbon group having 10 or more carbon atoms with —O—, and
the linking group (A3) represents an aromatic hydrocarbon group;
(B) a thermal acid generator (B-1) and/or a curing agent (B-2); and
(C) a solvent.

The protective film-forming composition against semiconductor wet etching solutions according to the present invention may also be applied as a resist underlayer film-forming composition as described later.

### Compound (A)

The term “having no repeating structural unit” means to exclude the so-called polymers having repeating structural units, such as polyolefins, polyesters, polyamides, and poly(meth)acrylates. The weight average molecular weight of the compound (A) is preferably 300 or more and 1,500 or less.

The “bond” between the terminal group (A1), the polyvalent group (A2), and the linking group (A3) means a chemical bond, and usually means a covalent bond, but the bond is not precluded from being an ionic bond.

The polyvalent group (A2) is a divalent to tetravalent group.

Therefore, the aliphatic hydrocarbon group in the definition of the polyvalent group (A2) is a divalent to tetravalent aliphatic hydrocarbon group.

Non-limiting examples of the divalent aliphatic hydrocarbon group include alkylene groups such as methylene, ethylene, n-propylene, sopropylene, cyclopropylene, n-butylene, isobutylene, s-butylene, t-butylene, cyclobutylene, 1-methyl-cyclopropylene, 2-methyl-cyclopropylene, n-pentylene, 1-methyl-n-butylene, 2-methyl-n-butylene, 3-methyl-n-butylene, 1,1-dimethyl-n-propylene, 1,2-dimethyl-n-propylene, 2,2-dimethyl-n-propylene, 1-ethyl-n-propylene, cyclopentylene, 1-methyl-cyclobutylene, 2-methyl-cyclobutylene, 3-methyl-cyclobutylene, 1,2-dimethyl-cyclopropylene, 2,3-dimethyl-cyclopropylene, 1-ethyl-cyclopropylene, 2-ethyl-cyclopropylene, n-hexylene, 1-methyl-n-pentylene, 2-methyl-n-pentylene, 3-methyl-n-pentylene, 4-methyl-n-pentylene, 1,1-dimethyl-n-butylene, 1,2-dimethyl-n-butylene, 1,3-dimethyl-n-butylene, 2,2-dimethyl-n-butylene, 2,3-dimethyl-n-butylene, 3,3-dimethyl-n-butylene, 1-ethyl-n-butylene, 2-ethyl-n-butylene, 1,1,2-trimethyl-n-propylene, 1,2,2-trimethyl-n-propylene, 1-ethyl-1 methyl-n-propylene, 1-ethyl-2-methyl-n-propylene, cyclohexylene, 1-methyl-cyclopentylene, 2-methyl-cyclopentylene, 3-methyl-cyclopentylene, 1-ethyl-cyclobutylene, 2-ethyl-cyclobutylene, 3-ethyl-cyclobutylene, 1,2-dimethyl-cyclobutylene, 1,3-dimethyl-cyclobutylene, 2,2-dimethyl-cyclobutylene, 2,3-dimethyl-cyclobutylene, 2,4-dimethyl-cyclobutylene, 3,3-dimethyl-cyclobutylene, 1-n-propyl-cyclopropylene, 2-n-propyl-cyclopropylene, 1-isopropyl-cyclopropylene, 2-isopropyl-cyclopropylene, 1,2,2-trimethyl-cyclopropylene, 1,2,3-trimethyl-cyclopropylene, 2,2,3-trimethyl-cyclopropylene, 1-ethyl-2-methyl-cyclopropylene, 2-ethyl-1-methyl-cyclopropylene, 2-ethyl-2-methyl-cyclopropylene, 2-ethyl-3-methyl-cyclopropylene, n-heptylene, n-octylene, n-nonylene, and n-decanylene groups.

Trivalent and tetravalent groups are derived from these groups by removing the hydrogen at any site and converting it to a bonding hand.

Examples of the aromatic hydrocarbon group having less than 10 carbon atoms in the definition of the polyvalent group (A2) include benzene, toluene, xylene, mesitylene, cumene, styrene, and indene.

Examples of the aliphatic hydrocarbon group combined with the aromatic hydrocarbon groups having less than 10 carbon atoms include above-described alkylene groups, and alkyl groups such as methyl, ethyl, n-propyl, i-propyl, cyclopropyl, n-butyl, i-butyl, s-butyl, t-butyl, cyclobutyl, 1-methyl-cyclopropyl, 2-methyl-cyclopropyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, cyclopentyl, 1-methyl-cyclobutyl, 2-methyl-cyclobutyl, 3-methyl-cyclobutyl, 1,2-dimethyl-cyclopropyl, 2,3-dimethyl-cyclopropyl, 1-ethyl-cyclopropyl, 2-ethyl-cyclopropyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2-trimethyl-n-propyl, 1,2,2-trimethyl-n-propyl, 1-ethyl-1-methyl-n-propyl, 1-ethyl-2-methyl-n-propyl, cyclohexyl, 1-methyl-cyclopentyl, 2-methyl-cyclopentyl, 3-methyl-cyclopentyl, 1-ethyl-cyclobutyl, 2-ethyl-cyclobutyl, 3-ethyl-cyclobutyl, 1,2-dimethyl-cyclobutyl, 1,3-dimethyl-cyclobutyl, 2,2-dimethyl-cyclobutyl, 2,3-dimethyl-cyclobutyl, 2,4-dimethyl-cyclobutyl, 3,3-dimethyl-cyclobutyl, 1-n-propyl-cyclopropyl, 2-n-propyl-cyclopropyl, 1-i-propyl-cyclopropyl, 2-i-propyl-cyclopropyl, 1,2,2-trimethyl-cyclopropyl, 1,2,3-trimethyl-cyclopropyl, 2,2,3-trimethyl-cyclopropyl, 1-ethyl-2-methyl-cyclopropyl, 2-ethyl-1-methyl-cyclopropyl, 2-ethyl-2-methyl-cyclopropyl, 2-ethyl-3-methyl-cyclopropyl, and decyl groups.

Any of the aromatic hydrocarbon group having less than 10 carbon atoms and the aliphatic hydrocarbon group in the definition of the polyvalent group (A2) may be bonded to the linking group (A3).

Examples of the aromatic hydrocarbon group having 10 or more carbon atoms in the definition of the polyvalent group (A2) include naphthalene, azulene, anthracene, phenanthrene, naphthacene, triphenylene, pyrene, and chrysene.

The aromatic hydrocarbon group having 10 or more carbon atoms in the definition of the polyvalent group (A2) is preferably bonded to the linking group (A3) via —O—.

Examples of the aromatic hydrocarbon group in the definition of the linking group (A3) include the aromatic hydrocarbon group having less than 10 carbon atoms and the aromatic hydrocarbon group having 10 or more carbon atoms.

Preferably, the compound (A) has two or more linking groups (A3).

Preferably, the compound (A) is represented by the following formula (II):

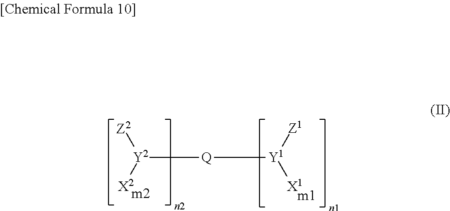

[in the formula (II),
Z¹ and Z² each independently represent any of the following structures:

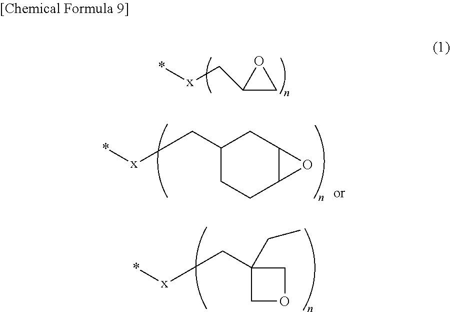

[in the formula (I), * represents a binding site with Y¹or Y²,
X represents an ether bond, an ester bond, or a nitrogen atom; n=1 when X is an ether bond or an ester bond, and n=2 when X is a nitrogen atom],
Y¹ and Y² each independently represent an aromatic hydrocarbon group,
X¹ and X² each independently represent —Y¹—Z¹ or —Y²—Z²,
n1 and n2 each independently represent an integer of 0 to 4, provided that any one of n1 and n2 is 1 or more,
m1 and m2 each independently represent 0 or 1,
Q represents a divalent to tetravalent group selected from the group consisting of —O—, an aliphatic hydrocarbon group, a combination of an aromatic hydrocarbon group having less than 10 carbon atoms with an aliphatic hydrocarbon group, and a combination of an aromatic hydrocarbon group having 10 or more carbon atoms with —O—].

In the formula (II), Z¹ and Z², Q, and Y¹ and Y² correspond to the terminal group (A1), the polyvalent group (A2), and the linking group (A3), respectively; and the same description, examples, and the like for the former apply to the latter.

Preferably, the compound (A) contains a partial structure represented by the following formula (III):

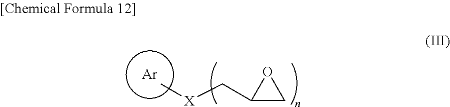

[in the formula (III), Ar represents a benzene ring, a naphthalene ring, or an anthracene ring; X represents an ether bond, an ester bond, or a nitrogen atom; n=1 when X is an ether bond or an ester bond, and n=2 when X is a nitrogen atom].

### (B) Thermal Acid Generator (B-1) and/or Curing Agent (B-2)

The protective film-forming composition of the present invention further comprises (B) a thermal acid generator (B-1) and/or a curing agent (B-2).

### Thermal Acid Generator (B-1)

Examples of the thermal acid generator include pyridinium-p-toluenesulfonate, pyridinium-trifluoromethanesulfonate, pyridinium-p-phenolsulfonate, K-PURE [registered trademark] CXC-1612, CXC-1614, TAG-2172, TAG-2179, TAG-2678, TAG-2689 (manufactured by King Industries, Inc.), and SI-45, SI-60, SI-80, SI-100, SI-110, and SI-150 (manufactured by Sanshin Chemical Industry Co., Ltd.).

These thermal acid generators may be used each alone or in combination of two or more thereof.

When the protective film-forming composition of the present invention contains a thermal acid generator, the lower limit of the content is usually 0.0001% by mass, preferably 0.01% by mass, and more preferably 0.1% by mass with respect to the total solid content of the protective film-forming composition, and the upper limit of the content is usually 20% by mass, preferably 15% by mass, and more preferably 10% by mass with respect to the total solid content of the protective film-forming composition.

### Curing Agent (B-2)

The curing agent used in the protective film-forming composition of the present invention is not particularly limited, and any generally known curing agent may be used. The curing agent is preferably selected from the group consisting of phenolic curing agents, amide-based curing agents, amine-based curing agents, imidazoles, acid anhydride-based curing agents, and organic phosphines.

### Phenolic Curing Agent

Examples of the phenolic curing agent include bisphenol A, bisphenol F, 4,4′-dihydroxydiphenylmethane, 4,4′-dihydroxydiphenyl ether, 1,4-bis(4-hydroxyphenoxy)benzene, 1,3-bis(4-hydroxyphenoxy)benzene, 4,4′-dihydroxydiphenyl sulfide, 4,4′-dihydroxydiphenyl ketone, 4,4′-dihydroxydiphenyl sulfone, 4,4′-dihydroxybiphenyl, 2,2′-dihydroxybiphenyl, 10-(2,5-dihydroxyphenyl)-10H-9-oxa-10-phosphaphenanthren-10-oxide, phenol novolac, bisphenol A novolac, o-cresol novolac, m-cresol novolac, p-cresol novolac, xylenol novolac, poly-p-hydroxystyrene, hydroquinone, resorcinol, catechol, t-butylcatechol, t-butylhydroquinone, fluoroglycinol, pyrogallol, t-butylpyrogallol, allylated pyrogallol, polyallylated pyrogallol, 1,2,4-benzenetriol, 2,3,4-trihydroxybenzophenone, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,4-dihydroxynaphthalene, 2,5-dihydroxynaphthalene, 2,6-dihydroxynaphthalene, 2,7-dihydroxynaphthalene, 2,8-dihydroxynaphthalene, allylated or polyallylated dihydroxynaphthalene, allylated bisphenol A, allylated bisphenol F, allylated phenolic novolac, and allylated pyrogallol.

### Amide-Based Curing Agent

Examples of the amide-based curing agent include dicyandiamide and derivatives thereof, and polyamide resins.

### Amine-Based Curing Agent

Examples of the amine-based curing agent include aliphatic amines, polyether amines, alicyclic amines, and aromatic amines.

Examples of the aliphatic amines include ethylenediamine, 1,3-diaminopropane, 1,4-diaminopropane, hexamethylenediamine, 2,5-dimethylhexamethylenediamine, trimethylhexamethylenediamine, diethylenetriamine, iminobispropylamine, bis(hexamethylene) triamine, triethylenetetramine, tetraethylenepentamine, pentaethylenehexamine, N-hydroxyethylethylenediamine, and tetra(hydroxyethyl)ethylenediamine.

Examples of the polyether amines include triethylene glycol diamine, tetraethylene glycol diamine, diethylene glycol bis(propylamine), polyoxypropylene diamine, and polyoxypropylene triamine.

Examples of the alicyclic amine include isophoronediamine, methacenediamine, N-aminoethylpiperazine, bis(4-amino-3-methyldicyclohexyl)methane, bis(aminomethyl)cyclohexane, 3,9-bis(3-aminopropyl)-2,4,8,10-tetraoxaspiro(5,5)undecane, and norbornenediamine.

Examples of the aromatic amines include tetrachloro-p-xylenediamine, m-xylenediamine, p-xylenediamine, m-phenylenediamine, o-phenylenediamine, p-phenylenediamine, 2,4-diaminoanisole, 2,4-toluenediamine, 2,4-diaminodiphenylmethane, 4,4′-diaminodiphenylmethane, 4,4′-diamino-1,2-diphenylethane, 2,4-diaminodiphenylsulfone, 4,4′-diaminodiphenylsulfone, m-aminophenol, m-aminobenzylamine, benzyldimethylamine, 2-dimethylaminomethyl)phenol, triethanolamine, methylbenzylamine, α-(m-aminophenyl)ethylamine, α-(p-aminophenyl)ethylamine, diaminodiethyldiphenylmethane, and α,α′-bis(4-aminophenyl)-p-diisopropylbenzene.

### Imidazole

Examples of the imidazole include 2-phenylimidazole, 2-ethyl-4(5)-methylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamidino-6-[2′-methylimidazolyl-(1′)]-ethyl-s-triazine, 2,4-diamidino-6-[2′-ethyl-4′-methylimidazolyl-(1′)]-ethyl-s-triazine, 2,4-diamidino-6-[2′-methylimidazolyl-(1′)]-ethyl-s-triazine isocyanurate adduct, 2-phenylimidazole isocyanurate adduct, 2-phenyl-4,5-dihydroxymethylimidazole, 2-phenyl-4-methyl-5hydroxymethylimidazole, and adducts of epoxy resins and the above imidazoles.

### Acid Anhydride-Based Curing Agent

Examples of the acid anhydride-based curing agent include acid anhydrides and modified acid anhydrides.

Examples of the acid anhydride include phthalic anhydride, trimellitic anhydride, pyromellitic anhydride, benzophenone tetracarboxylic anhydride, dodecenyl succinic anhydride, polyadipic anhydride, polyazelaic anhydride, polysebacic anhydride, poly(ethyloctadecanedioic acid) anhydride, poly (phenylhexadecanedioic acid) anhydride, tetrahydrophthalic anhydride, methyl tetrahydrophthalic anhydride, methyl hexahydrophthalic anhydride, hexahydrophthalic anhydride, methyl hymic anhydride, tetrahydrophthalic anhydride, trialkyltetrahydrophthalic anhydride, methyl cyclohexene dicarboxylic anhydride, methyl cyclohexene tetracarboxylic anhydride, ethylene glycol bistrimellitate dianhydride, het anhydride, nadic anhydride, methyl nadic anhydride, 5-(2,5-dioxotetrahydro-3-furanyl)-3-methyl-3-cyclohexane-1,2-dicarboxylic acid anhydride, 3,4-dicarboxy-1,2,3,4-tetrahydro-1-naphthalene succinic acid dianhydride, and 1-methyl-dicarboxy-1,2,3,4-tetrahydro-1-naphthalene succinic acid dianhydride.

Examples of the modified acid anhydride include glycol-modified products of the above acid anhydrides. Examples of the glycol that may be used for modification include alkylene glycols such as ethylene glycol, propylene glycol, and neopentyl glycol; and polyether glycols such as polyethylene glycol, polypropylene glycol, and polytetramethylene ether glycol. Moreover, copolymerized polyether glycols of two or more species of these glycols and/or polyether glycols may also be used. The modified acid anhydride is preferably modified with 0.4 mol or less of glycol per mole of acid anhydride.

### Organic Phosphines

Examples of the organic phosphines include tributylphosphine, methyldiphenylphosphine, triphenylphosphine, diphenylphosphine, and phenylphosphine.

Examples of the phosphonium salt include tetraphenylphosphonium tetraphenylborate, tetraphenylphosphonium ethyltriphenylborate, and tetrabutylphosphonium tetrabutylborate.

Examples of the tetraphenylboron salt include 2-ethyl-4-methylimidazole tetraphenylborate and N-methylmorpholine-tetraphenylborate.

### Other Curing Agents

Examples of other curing agents include mercaptan-based curing agents, tertiary amines, phosphonium salts, tetraphenylboron salts, organic acid dihydrazide, halogenated boroamine complexes, isocyanate-based curing agents, and blocked isocyanate-based curing agents.

These curing agents may be used each alone or in combination of two or more thereof.

When the protective film-forming composition of the present invention contains a curing agent, the lower limit of the content is usually 0.0001% by mass, preferably 0.01% by mass, and more preferably 0.1% by mass with respect to the total solid content of the protective film-forming composition, and the upper limit of the content is usually 50% by mass, preferably 40% by mass, and more preferably 30% by mass with respect to the total solid content of the protective film-forming composition.

### Solvent (C)

The protective film-forming composition of the present invention may be prepared by dissolving each of the above components in a solvent, preferably an organic solvent, and is used in a uniform solution state.

The organic solvent of the protective film-forming composition according to the present invention may be used without particular limitation as long as it is an organic solvent capable of dissolving the component (A), the component (B), and other optional solid components. In particular, since the protective film-forming composition of the present invention is used in a uniform solution state, it is recommended that it be used in combination with an organic solvent commonly used in a lithography process in consideration of its application property.

Examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanisol, methoxy cyclopentane, anisole, γ-butyrolactone, N-methylpyrrolidone, N, N-dimethylformamide, and N,N-dimethylacetamide. These solvents may be used each alone or in combination of two or more thereof.

Of these solvents, propylene glycol monomethyl ether, propylene glycol monomethyl ether acetate, ethyl lactate, butyl lactate, cyclohexanone, and the like are preferable. In particular, propylene glycol monomethyl ether and propylene glycol monomethyl ether acetate are preferable.

The solid content of the protective film-forming composition according to the present invention is usually within the range of from 0.1 to 70% by mass, and preferably from 0.1 to 60% by mass The solid content is the percentage of all components in the protective film-forming composition minus the solvent. The proportion of the compound (A) in the solid content is, with the increasing preference, within the range of from 1 to 100% by mass, from 1 to 99.9% by mass, from 50 to 99.9% by mass, from 50 to 95% by mass, and from 50 to 90% by mass.

### Component (D)

The protective film-forming composition according to the present invention may further include a compound (D) having one phenolic hydroxy group or a polymer having a unit structure having one phenolic hydroxy group.

By the term “compound having one phenolic hydroxy group or polymer having a unit structure having one phenolic hydroxy group”, any compounds or polymers having phenolic hydroxy groups such as catechol are excluded.

The compound having one phenolic hydroxy group or the polymer having a unit structure having one phenolic hydroxy group is not particularly limited as long as it is a compound or polymer that does not impair the advantageous effect of the present invention.

The weight average molecular weight of the compound having one phenolic hydroxy group or the polymer having a unit structure having one phenolic hydroxy group is also not particularly limited, and is, for example, within the range of from 300 to 50,000 or from 1,000 to 50,000.

The polymer having a unit structure having one phenolic hydroxy group preferably contains a unit structure represented by the following formula (3-1):

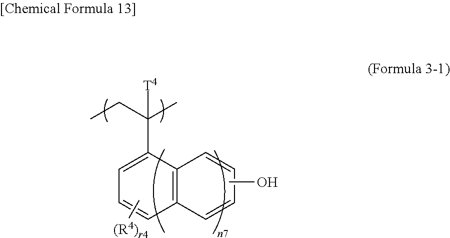

(in the formula, T⁴ represents a hydrogen atom or an alkyl group having 1 to 10 carbon atoms which may be substituted with a halogeno group; R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, an alkyl group having 1 to 10 carbon atoms which may be substituted with a hydroxy group or a halogeno group; r4 represents an integer of 0 to 3; n7 represents an integer of 0 to 2; and a is 1).

Examples of the halogeno group include fluorine, chlorine, bromine, and iodine.

Examples of the alkyl group having 1 to 10 carbon atoms include methyl, ethyl, n-propyl, i-propyl, cyclopropyl, n-butyl, i-butyl, s-butyl, t-butyl, cyclobutyl, 1-methyl-cyclopropyl, 2-methyl-cyclopropyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, cyclopentyl, 1-methyl-cyclobutyl, 2-methyl-cyclobutyl, 3-methyl-cyclobutyl, 1,2-dimethyl-cyclopropyl, 2,3-dimethyl-cyclopropyl, 1-ethyl-cyclopropyl, 2-ethyl-cyclopropyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2-trimethyl-n-propyl, 1,2,2-trimethyl-n-propyl, 1-ethyl-1-methyl-n-propyl, 1-ethyl-2-methyl-n-propyl, cyclohexyl, 1-methyl-cyclopentyl, 2-methyl-cyclopentyl, 3-methyl-cyclopentyl, 1-ethyl-cyclobutyl, 2-ethyl-cyclobutyl, 3-ethyl-cyclobutyl, 1,2-dimethyl-cyclobutyl, 1,3-dimethyl-cyclobutyl, 2,2-dimethyl-cyclobutyl, 2,3-dimethyl-cyclobutyl, 2,4-dimethyl-cyclobutyl, 3,3-dimethyl-cyclobutyl, 1-n-propyl-cyclopropyl, 2-n-propyl-cyclopropyl, 1-i-propyl-cyclopropyl, 2-i-propyl-cyclopropyl, 1,2,2-trimethyl-cyclopropyl, 1,2,3-trimethyl-cyclopropyl, 2,2,3-trimethyl-cyclopropyl, 1-ethyl-2-methyl-cyclopropyl, 2-ethyl-1-methyl-cyclopropyl, 2-ethyl-2-methyl-cyclopropyl, 2-ethyl-3-methyl-cyclopropyl, and decyl groups.

Examples of the alkoxy group having 1 to 9 carbon atoms include methoxy, ethoxy, n-propoxy, isopropoxy, n-butoxy, isobutoxy, tert-butoxy, sec-butoxy, n-pentoxy, neopentoxy, n-hexyloxy, isohexyloxy, and 3-methylpentoxy groups.

The polymer having a unit structure having one phenolic hydroxy group preferably has at least three or more repeating unit structures.

The polymer having a unit structure having one phenolic hydroxy group may be a polymer containing one type of unit structure represented by the formula (3-1) or a copolymer containing two or more types thereof.

Specific examples of the polymer having a unit structure having one phenolic hydroxy group include polymers containing the unit structures shown below.

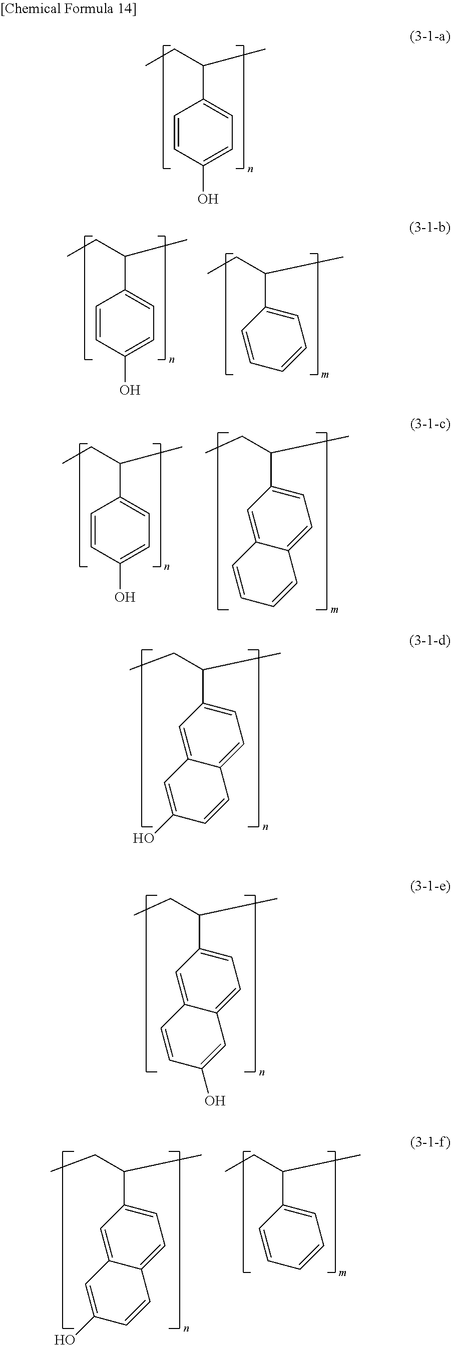

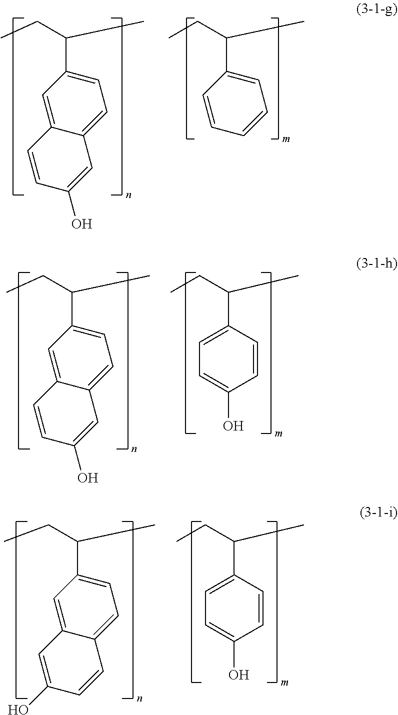

(wherein in the above formulas, m and n next to the repeating unit represent the molar ratio of copolymerization)

The protective film-forming composition against semiconductor wet etching solutions according to the present invention preferably does not contain a novolak resin. It is also preferable that each of the compound (A), the component (B), and the solvent (C) does not contain a material containing one or more aromatic groups containing two or more substituents containing a hydroxy, thiol, and/or amine moiety.

### Protective Film, Resist Underlayer Film, Substrate with Protective Film/Substrate with Resist Pattern, and Method for Producing Semiconductor Device

Hereinafter, a method for producing a substrate with a protective film/a substrate with a resist pattern using the protective film-forming composition/the resist underlayer film-forming composition according to the present invention, and a method for producing a semiconductor device will be described.

The substrate with a protective film/substrate with a resist pattern according to the present invention may be produced by applying the above-described protective film-forming composition/resist underlayer film-forming composition onto a semiconductor substrate followed by the baking thereof.

Examples of the semiconductor substrate to which the protective film-forming composition/resist underlayer film-forming composition of the present invention is applied include silicon wafers, germanium wafers, and semiconductor wafers such as gallium arsenide, indium phosphide, titanium nitride, gallium nitride, indium nitride, aluminum nitride, and aluminum oxide.

When a semiconductor substrate having an inorganic film formed on its surface is used, the inorganic film may be formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a low-temperature oxide film, a polysilicon film, a silicon oxide film, a silicon nitride film, a silicon oxynitride film, a boro-phospho silicate glass (BPSG) film, a titanium nitride film, a titanium oxynitride film, a tungsten nitride film, a gallium nitride film, aluminum oxide, hafnium oxide, tantalum, tantalum nitride, and a gallium arsenide film The semiconductor substrate may be a stepped substrate, in which the so-called vias (holes), trenches (grooves), and the like are formed. For example, the via has a substantially circular shape when viewed from the upper surface, the diameter of the substantially circular shape is, for example, within the range of from 2 nm to 20 nm, and the depth is within the range of from 50 nm to 500 nm, and the width of the trench (recess of the substrate) is, for example, within the range of from 1 nm to 20 nm, and the depth is within the range of from 50 nm to 500 nm. Because the protective film-forming composition/resist underlayer film-forming composition of the present invention has a small weight average molecular weight and average particle size of the compound included in the composition, the composition can be embedded even in the stepped substrate as mentioned above without defects such as voids. The absence of defects such as voids is an important characteristic for the next process of semiconductor manufacturing (wet etching/dry etching of semiconductor substrate and resist pattern formation).

The protective film-forming composition/resist underlayer film-forming composition of the present invention is applied onto such a semiconductor substrate by an appropriate application method such as a spinner or a coater. Thereafter, baking is performed using a heating means such as a hot plate to form a protective film/resist underlayer film. The baking conditions are appropriately selected from a baking temperature of from 100° C. to 400° C. and a baking time of from 0.3 minutes to 60 minutes. Preferably, the baking temperature is from 120° C. to 350° C. and the baking time is from 0.5 minutes to 30 minutes, and more preferably, the baking temperature is from 150° C. to 300° C. and the baking time is from 0.8 minutes to 10 minutes. The thickness of the protective film/resist underlayer film to be formed is, for example, within the range of from 0.001 μm to 10 μm, preferably from 0.002 μm to 1 μm, and more preferably from 0.005 μm to 0.5 μm. When the temperature during the baking is lower than the above range, crosslinking may be insufficient, and resistance of the protective film/resist underlayer film to be formed against a resist solvent or a basic hydrogen peroxide aqueous solution may be difficult to obtain. To the contrary, when the temperature during the baking is higher than the above range, the protective film/resist underlayer film may be decomposed by heat.

The exposure is performed through a mask (reticle) for forming a predetermined pattern using, for example, i-ray, KrF excimer laser, ArF excimer laser, EUV (extreme ultraviolet ray), or EB (electron beam). An alkaline developer is used for development, and the development temperature is selected from 5° C. to 50° C. and the development time from 10 seconds to 300 seconds. Examples of the alkaline developer include aqueous solutions of inorganic alkalis such as sodium hydroxide, potassium hydroxide, sodium carbonate, sodium silicate, sodium metasilicate, and ammonia water, primary amine such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine. In addition, an alcohol such as isopropyl alcohol and a surfactant such as nonionic surfactants may be added in an appropriate amount to the above aqueous alkali solutions. Of these developers, quaternary ammonium salts are preferred, and tetramethylammonium hydroxide and choline are more preferred. In addition, a surfactant and other agents may be added to these developers. A method of developing a photoresist with an organic solvent such as butyl acetate instead of an alkaline developer may be used to develop a portion of the photoresist where the alkali dissolution rate is not improved.

Next, the protective film/resist underlayer film is dry-etched using the formed resist pattern as a mask At that time, when the inorganic film is formed on the surface of the used semiconductor substrate, the surface of the inorganic film is allowed to be exposed. When the inorganic film is not formed on the surface of the used semiconductor substrate, the surface of the semiconductor substrate is allowed to be exposed.

The protective film/resist underlayer film of the present application may also be applied to a lithography process using a combination of a resist and another material (for example, a combination of a resist with a silicon oxide film under the resist) on the upper layer.

Further, a desired pattern is formed by wet etching with a semiconductor wet etching solution using the dry-etched protective film/resist underlayer film (and the resist pattern, if any, remaining on the protective film/resist underlayer film) as a mask.

The semiconductor wet etching solution may be a general chemical solution for etching semiconductor wafers, such as substances exhibiting acidity or basicity.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic aqueous solution of hydrogen peroxide obtained by mixing aqueous solution of hydrogen peroxide with an organic amine such as ammonia, sodium hydroxide, potassium hydroxide, sodium cyanide, potassium cyanide, or triethanolamine to make the pH basic. Specific examples thereof include SC-1 (ammonia-hydrogen peroxide solution). In addition, any solution capable of creating basic pH, for example, a mixture of urea in an aqueous solution of hydrogen peroxide, which can ultimately be create basic pH by heat-induced thermal decomposition of urea to generate ammonia, may also be used as a chemical solution for wet etching.

Of these, acidic or basic aqueous solution of hydrogen peroxide is preferable.

These chemical solutions may contain an additive such as a surfactant.

The use temperature of the semiconductor wet etching solution is desirably from 25° C. to 90° C., and more desirably from 40° C. to 80° C. The wet etching time is desirably from 0.5 minutes to 30 minutes, and more desirably from 1 minute to 20 minutes.

### EXAMPLES

The following examples are provided to illustrate the present invention in detail, but the invention is not limited to these examples.

The weight average molecular weight of the compounds shown in the following Examples 1 to 4 and Synthesis Example 1 in the present description is the result of the measurement by gel permeation chromatography (hereinafter, abbreviated as GPC). For the measurement, a GPC apparatus manufactured by Tosoh Corporation was used, and the conditions for measurement and the like are as follows.
GPC column: TSKgel guard column SuperMP (HZ)-N, TSKgel SuperMultipore HZ-N (P009), TSKgel SuperMultipore HZ-N (P0010) (manufactured by Tosoh Corporation)
Column temperature: 40° C.
Solvent: tetrahydrofuran (THF)
Flow rate: 0.35 ml/min
Standard sample: polystyrene (manufactured by Tosoh Corporation)

### Example 1

To 3.56 g of tetraphenylol ethane tetraglycidyl ether (manufactured by Nippon Kayaku Co., Ltd., product name 10315) (weight average molecular weight: 1,033) were added 0.036 g of K-PURE [registered trademark] TAG-2689 (manufactured by King Industries, Inc.) as a thermal acid generator, 77.12 g of propylene glycol monomethyl ether acetate, and 19.28 g of propylene glycol monomethyl ether, to prepare a solution. The solution was filtered through a polyethylene microfilter having a pore size of 0.02 μm to prepare a protective film-forming composition.

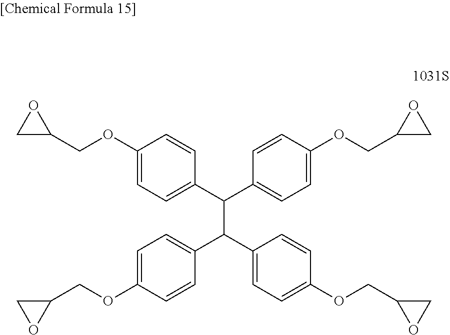 [SMILES: c1cc(C(c2ccc(OCC3CO3)cc2)C(c2ccc(OCC3CO3)cc2)c2ccc(OCC3CO3)cc2)ccc1OCC1CO1]

### Example 2

To 1.78 g of 2-[4-(2,3-epoxypropoxy)phenyl]-2-(4-[1,1-bis [4-[2,3-epoxypropoxy]phenyl)ethyl]phenyl]propane (manufactured by Mitsubishi Chemical Corporation, product name NC-6000) (weight average molecular weight: 548) were added 0.018 g of K-PURE [registered trademark] TAG-2689 (manufactured by King Industries, Ltd.) as a thermal acid generator, 33.56 g of propylene glycol monomethyl ether acetate, and 9.64 g of propylene glycol monomethyl ether, to prepare a solution. The solution was filtered through a polyethylene microfilter having a pore size of 0.02 μm to prepare a protective film-forming composition.

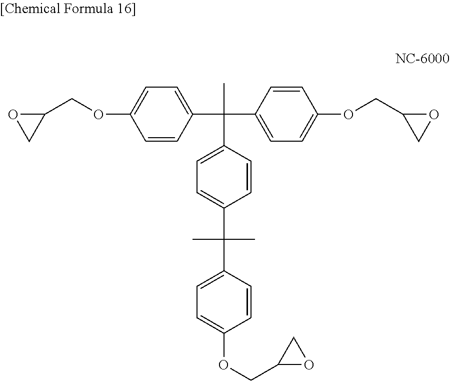 [SMILES: CC(C)(c1ccc(OCC2CO2)cc1)c1ccc(C(C)(c2ccc(OCC3CO3)cc2)c2ccc(OCC3CO3)cc2)cc1]

### Example 3

To 2.85 g of a commercially available epoxy resin (manufactured by DIC Corporation, product name EPICLON HP-6000) (weight average molecular weight: 361, containing a compound of the following structural formula) were added 0.029 g of K-PURE [registered trademark] TAG-2689 (manufactured by King Industries, Inc.) as a thermal acid generator, 61.70 g of propylene glycol monomethyl ether acetate, and 15.42 g of propylene glycol monomethyl ether, to prepare a solution. The solution was filtered through a polyethylene microfilter having a pore size of 0.02 μm to prepare a protective film-forming composition.

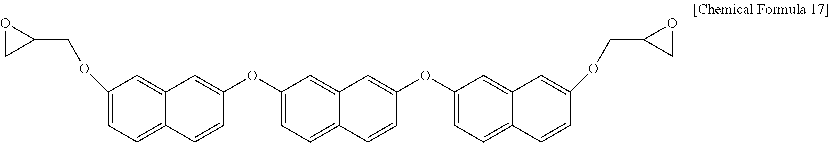 [SMILES: c1cc2ccc(Oc3ccc4ccc(Oc5ccc6ccc(OCC7CO7)cc6c5)cc4c3)cc2cc1OCC1CO1]

### Example 4

To 0.83 g of 2-[4-(2,3-epoxypropoxy)phenyl]-2-[1,1-bis[4-([2,3-epoxypropoxy]phenyl)ethyl]phenyl] propane (manufactured by Mitsubishi Chemical Corporation, product name NC-6000) (weight average molecular weight: 548) and 0.28 g of VP-2500 (manufactured by Nippon Soda Co., Ltd., corresponding to Formula (A), weight average molecular weight: 3,687) (30% by mass PGMEA solution) were added 0.083 g of K-PURE [registered trademark] TAG-2689 (manufactured by King Industries, Inc.) as a thermal acid generator, 0.083 g of R-40 LM (DIC Corporation) (1% by mass PGMEA solution), 15.18 g of propylene glycol monomethyl ether acetate, and 6.62 g of propylene glycol monomethyl ether, to prepare a solution. The solution was filtered through a polyethylene microfilter having a pore size of 0.02 μm to prepare a protective film-forming composition.

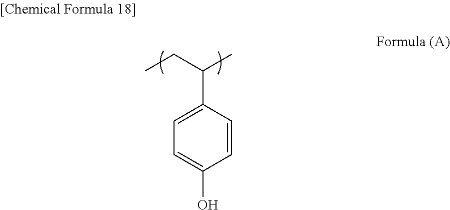

### Synthesis Example 1

A solution of 5.50 g of glycerin monomethacrylate (product name BLEMMER GLM, manufactured by Nof Corporation), 5.09 g of 5-vinylbenzo[d][1,3]dioxole (manufactured by Cool Pharm LTD.), and 0.66 g of 2,2′-azobis(isobutyronitrile) (manufactured by Tokyo Chemical Industry Co., Ltd.) in 35.99 g of propylene glycol monomethyl ether was added to a dropping funnel, and the solution was added dropwise at 100° C. under a nitrogen atmosphere into a reaction flask containing 9.00 g of propylene glycol monomethyl ether. The resultant mixture was heated and stirred for 17 hours. To the obtained solution, 11 g of a cation exchange resin (product name Dow X [registered trademark] 550A, Muromati Technos Co., Ltd.) and 11 g of an anion exchange resin (product name Amberlite [registered trademark] 15 JWET, Organo Corporation) were added, and the solution was subjected to ion exchange treatment at room temperature for 4 hours. The ion exchange resin was separated to obtain a resin solution corresponding to Formula (B). The resin had a weight average molecular weight (Mw) measured in terms of polystyrene by GPC of 10,800.

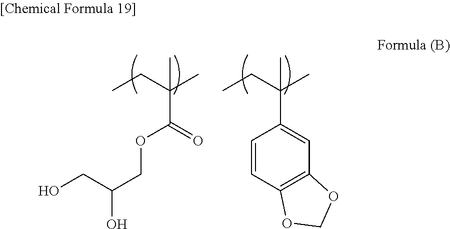

### Comparative Example 1

To 6.6 g of the resin solution (solid content: 17.4 wt %) obtained in Synthesis Example 1 were added 0.06 g of pyridinium trifluoromethanesulfonic acid (manufactured by ADEKA Corporation) as a crosslinking acid catalyst, 0.001 g of a surfactant (product name MEGAFACE [trade name] R-40 manufactured by DIC Corporation, fluorine-based surfactant), 11.5 g of propylene glycol monomethyl ether, and 1.9 g of propylene glycol monomethyl ether acetate, to prepare a solution of a protective film-forming composition.

### Formation of Coating Film

Each of the protective film-forming compositions prepared in Examples 1 to 4 and the film-forming composition prepared in Comparative Example 1 was applied by spin coating onto a silicon substrate carrying a titanium nitride film formed on its surface. Baking the applied film at 250° C. for 60 seconds gave a coating film having a film thickness of 100 nm.

### Test of Resistance to Basic Hydrogen Peroxide Aqueous Solution

The coating films prepared on silicon substrate carrying a titanium nitride film formed on the surface with each of the protective film-forming compositions prepared in Examples 1 to 4 and the film-forming composition prepared in Comparative Example 1 were immersed in a basic hydrogen peroxide aqueous solution having a composition shown in Table 1 below at a temperature shown in the same table for 4 minutes. Thereafter, the coating films were washed with water and dried, and then the state of the coating films was visually observed. The results are shown in Table 2 below. In Table 2, the symbol “∘” indicates that no peeling was observed in the coating film after 4 minutes of treatment, and the symbol “x” indicates that peeling was observed in a part or entire coating film after 4 minutes of treatment.

TABLE 1

| 28% by mass | 33% by mass hydrogen | Ultrapure | |
|---|---|---|---|
| ammonia solution | peroxide solution | water | Temperature |
| 40 ml | 40 ml | 80 ml | 50° C. |

TABLE 2

| Example 1 | Example 2 | Example 3 | Example 4 | Comparative Example 1 |
|---|---|---|---|---|
| ∘ | ∘ | ∘ | ∘ | x |

The results in the above table showed that the coating films produced using the protective film-forming compositions prepared in Examples 1 to 3 had a sufficient resistance to basic hydrogen peroxide aqueous solutions. That is, it was found that these coating films would be able to serve as protective films against basic hydrogen peroxide aqueous solutions. To the contrary, the coating film prepared using the film-forming composition prepared in Comparative Example 1 was found to be insufficient as a protective film against a basic hydrogen peroxide aqueous solution.

### Test of Optical Parameters

Each of the protective film-forming compositions prepared in Examples 1 to 4 and Comparative Example 1 was applied onto a silicon wafer by a spinner. The applied film was baked on a hot plate at 250° C. for 1 minute to form a resist underlayer film (film thickness: 50 nm). Then, the n value (refractive index) and the k value (attenuation coefficient or absorption coefficient) of the films from each of these protective film-forming compositions were measured at a wavelength of 193 nm and a wavelength of 193 nm using a spectroscopic ellipsometer (J. A. Woollam, VUV-VASE VU-302). The results are shown in Table 3.

### Measurement of Dry Etching Rate

Each of the protective film-forming compositions prepared in Example 1 to 4 and Comparative Example 1 was applied onto a silicon wafer by a spin coater. The applied film was baked on a hot plate at 250° C. for 1 minute to form a resist underlayer film. Then, the dry etching rate (decrease in film thickness per unit time) was measured with a dry etching apparatus (RIE-10NR) manufactured by Samco Inc. under the conditions of using Na (200 sccm), O₂ (10 sccm), and RF (60 W) as dry etching gases.

The dry etching rate given by each of the protective film-forming compositions prepared in Examples 1 to 4 was compared with the dry etching rate given by the protective film-forming composition prepared in Comparative Example 1. Table 3 shows the dry etching rate given by each of the protective film-forming compositions of Examples as “selectivity” taking the dry etching rate given by Comparative Example 1 as 1.00.

TABLE 3

| | n/k @193 nm | n/k @248 nm | Selectivity |
|---|---|---|---|
| Example 1 | 1.49/0.69 | 1.88/0.15 | 0.7 |
| Example 2 | 1.49/0.72 | 1.92/0.04 | 0.7 |
| Example 3 | 1.49/0.43 | 1.87/0.49 | 0.6 |
| Example 4 | 1.50/0.75 | 1.92/0.04 | 0.7 |
| Comparative Example 1 | 1.47/0.32 | 1.71/0.04 | 1.0 |

The above results showed that the dry etching rates given by the protective film-forming compositions prepared in Examples 1 to 4 according to the present invention were lower than the dry etching rate given by the protective film-forming composition prepared in Comparative Example 1. Thus, it can be said that the protective film according to the present application has an etching resistance under the dry etching conditions.

### INDUSTRIAL APPLICABILITY

The protective film-forming composition according to the present invention permits formation of a protective film exhibiting a high chemical resistance, good optical parameters, and a desirable dry etching selectivity in a lithography process for the manufacture of semiconductors.

1. A protective film-forming composition against semiconductor wet etching solutions, comprising:
(A) a compound having no repeating structural unit,
which contains a terminal group (A1), a multivalent group (A2), and a linking group (A3),
wherein the terminal group (A1) is bonded only to the linking group (A3),
the polyvalent group (A2) is bonded only to the linking group (A3), and
the linking group (A3) is bonded to the terminal group (A1) on one side and to the polyvalent group (A2) on the other, and may optionally be linked to another linking group (A3),
the terminal group (A1) has any of the structures of the following formula (I): 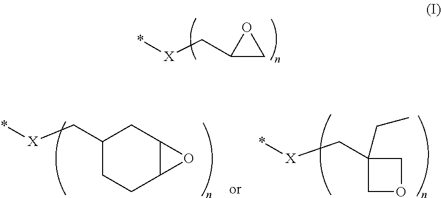
[in the formula (I), * represents a binding site with the linking group (A3),
X represents an ether bond, an ester bond, or a nitrogen atom; n=1 when X is an ether bond or an ester bond, and n=2 when X is a nitrogen atom],
the polyvalent group (A2) is a divalent to tetravalent group selected from the group consisting of:
—O—,
an aliphatic hydrocarbon group,
a combination of an aromatic hydrocarbon group having less than 10 carbon atoms with an aliphatic hydrocarbon group, and
a combination of an aromatic hydrocarbon group having 10 or more carbon atoms with —O—, and
the linking group (A3) represents an aromatic hydrocarbon group;
(B) a thermal acid generator (B-1) and/or a curing agent (B-2); and
(C) a solvent.

2. The protective film-forming composition according to claim 1, wherein the compound (A) is a compound represented by the following formula (II): 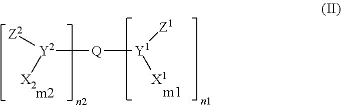
[in the formula (II), Z¹ and Z² each independently represent any of the following structures: 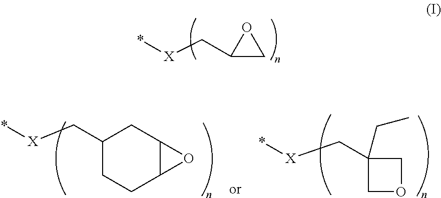
[in the formula (I), * represents a binding site with Y¹ or Y²,
X represents an ether bond, an ester bond, or a nitrogen atom; n=1 when X is an ether bond or an ester bond, and n=2 when X is a nitrogen atom],
Y¹ and Y² each independently represent an aromatic hydrocarbon group,
X¹ and X² each independently represent —Y¹—Z¹ or —Y²—Z²,
n1 and n2 each independently represent an integer of 0 to 4, provided that any one of n1 and n2 is 1 or more,
m1 and m2 each independently represent 0 or 1,
Q represents a divalent to tetravalent group selected from the group consisting of —O—, an aliphatic hydrocarbon group, a combination of an aromatic hydrocarbon group having less than 10 carbon atoms with an aliphatic hydrocarbon group, and a combination of an aromatic hydrocarbon group having 10 or more carbon atoms with —O—].

3. The protective film-forming composition according to claim 1,
wherein the compound (A) contains a partial structure represented by the following formula (III): 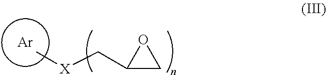
[in the formula (III), Ar represents a benzene ring, a naphthalene ring or an anthracene ring; X represents an ether bond, an ester bond, or a nitrogen atom; n=1 when X is an ether bond or an ester bond, and n=2 when X is a nitrogen atom].

4. The protective film-forming composition according to claim 1,
wherein the compound (A) has a weight average molecular weight of 300 or more and 1,500 or less.

5. The protective film-forming composition according to claim 1, wherein the composition is free from a novolak resin.

6. The protective film-forming composition according to claim 1, wherein each of the compound (A), the component (B), and the solvent (C) is free from a material containing one or more aromatic groups containing two or more substituents containing a hydroxy, thiol, and/or amine moiety.

7. The protective film-forming composition according to claim 1, wherein the compound (A) has two or more of the linking groups (A3).

8. The protective film-forming composition according to claim 1, wherein the component (B) comprises a curing agent (B-2) selected from the group consisting of phenolic curing agents, amide-based curing agents, amine-based curing agents, imidazoles, acid anhydride-based curing agents, and organic phosphines.

9. The protective film-forming composition according to claim 1, further comprising (D) a compound having one phenolic hydroxy group or a polymer having a unit structure having one phenolic hydroxy group.

10. A protective film, which is a baked product of a coating film of the protective film-forming composition according to claim 1.

11. A resist underlayer film-forming composition comprising:
(A) a compound having no repeating structural unit,
which contains a terminal group (A1), a multivalent group (A2), and a linking group (A3),
wherein the terminal group (A1) is bonded only to the linking group (A3),
the polyvalent group (A2) is bonded only to the linking group (A3), and
the linking group (A3) is bonded to the terminal group (A1) on one side and to the polyvalent group (A2) on the other, and may optionally be linked to another linking group (A3),
the terminal group (A1) has any of the structures of the following formula (I): 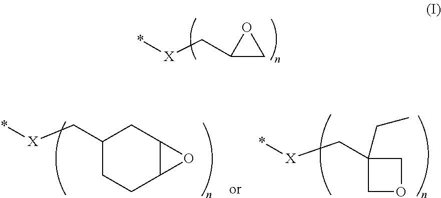
[in the formula (I), * represents a binding site with the linking group (A3),
X represents an ether bond, an ester bond, or a nitrogen atom; n=1 when X is an ether bond or an ester bond, and n=2 when X is a nitrogen atom],
the polyvalent group (A2) is a divalent to tetravalent group selected from the group consisting of:
—O—,
an aliphatic hydrocarbon group,
a combination of an aromatic hydrocarbon group having less than 10 carbon atoms with an aliphatic hydrocarbon group, and
a combination of an aromatic hydrocarbon group having 10 or more carbon atoms with —O—, and
the linking group (A3) represents an aromatic hydrocarbon group;
(B) a thermal acid generator (B-1) and/or a curing agent (B-2); and
(C) a solvent.

12. The resist underlayer film-forming composition according to claim 11, wherein the compound (A) is a compound represented by the following formula (II): 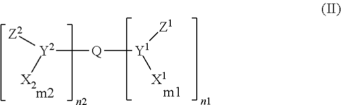
[in the formula (II), Z¹ and Z² each independently represent any of the following structures: 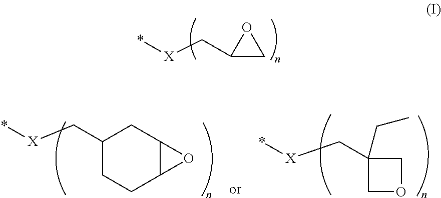
[in the formula (I), * represents a binding site with Y¹ or Y²,
X represents an ether bond, an ester bond, or a nitrogen atom; n=1 when X is an ether bond or an ester bond, and n=2 when X is a nitrogen atom],
Y¹ and Y² each independently represent an aromatic hydrocarbon group,
X¹ and X² each independently represent —Y¹—Z¹ or —Y²—Z²,
n1 and n2 each independently represent an integer of 0 to 4, provided that any one of n1 and n2 is 1 or more,
m1 and m2 each independently represent 0 or 1,
Q represents a divalent to tetravalent group selected from the group consisting of —O—, an aliphatic hydrocarbon group, a combination of an aromatic hydrocarbon group having less than 10 carbon atoms with an aliphatic hydrocarbon group, and a combination of an aromatic hydrocarbon group having 10 or more carbon atoms with —O—].

13. The resist underlayer film-forming composition according to claim 11,
wherein the compound (A) contains a partial structure represented by the following formula (III): 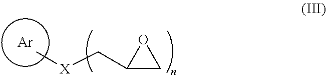
[in the formula (III), Ar represents a benzene ring, a naphthalene ring or an anthracene ring; X represents an ether bond, an ester bond, or a nitrogen atom; n=1 when X is an ether bond or an ester bond, and n=2 when X is a nitrogen atom].

14. The resist underlayer film-forming composition according to claim 11,
wherein the compound (A) has a weight average molecular weight of 300 or more and 1,500 or less.

15. The resist underlayer film-forming composition according to claim 11, wherein the composition is free from a novolak resin.

16. The resist underlayer film-forming composition according to claim 11, wherein each of the compound (A), the component (B), and the solvent (C) is free from a material containing one or more aromatic groups containing two or more substituents containing a hydroxy, thiol, and/or amine moiety.

17. The resist underlayer film-forming composition according to claim 11, wherein the compound (A) has two or more of the linking groups (A3).

18. The resist underlayer film-forming composition according to claim 11, wherein the component (B) comprises a curing agent (B-2) selected from the group consisting of phenolic curing agents, amide-based curing agents, amine-based curing agents, imidazoles, acid anhydride-based curing agents, and organic phosphines.

19. The resist underlayer film-forming composition according to claim 11, further comprising (D) a compound having one phenolic hydroxy group or a polymer having a unit structure having one phenolic hydroxy group.

20. A resist underlayer film, which is a baked product of a coating film of the resist underlayer film-forming composition according to claim 11.

21. A method for producing a substrate with a protective film used in the manufacture of semiconductors, comprising applying the protective film-forming composition according to claim 1 onto a stepped semiconductor substrate followed by baking thereof to form a protective film.

22. A method for producing a substrate with a resist pattern used in the manufacture of semiconductors, comprising:
applying the protective film-forming composition according to claim 1 onto a semiconductor substrate followed by baking thereof to form a protective film as a resist underlayer film; and
forming a resist film on the protective film followed by exposure and development thereof to form a resist pattern.

23. A method for producing a semiconductor device, comprising:
forming a protective film on a semiconductor substrate, which may have an inorganic film formed on its surface, with the protective film-forming composition according to claim 1;
forming a resist pattern on the protective film;
dry etching the protective film using the resist pattern as a mask;
allowing a surface of the inorganic film or the semiconductor substrate to expose; and
wet etching and cleaning the inorganic film or the semiconductor substrate with a semiconductor wet etching solution using the dry-etched protective film as a mask.

24. A method for producing a semiconductor device, comprising:
forming a resist underlayer film on a semiconductor substrate, which may have an inorganic film formed on its surface, with the resist underlayer film-forming composition according to claim 11;
forming a resist pattern on the resist underlayer film;
dry etching the resist underlayer film using the resist pattern as a mask;
allowing a surface of the inorganic film or the semiconductor substrate to expose; and
etching the inorganic film or the semiconductor substrate using the dry-etched resist underlayer film as a mask.
